(19) United States
(12) Patent Application Publication
(10) Pub. No.: US 2010/0065949 A1
(43) Pub. Date: Mar. 18, 2010

(54) Stacked Semiconductor Chips with Through Substrate Vias

(76) Inventors: Andreas Thies, Berlin (DE); Harry Hedler, Germering (DE); Roland Irsigler, Muenchen (DE)

Correspondence Address: SLATER & MATSIL, L.L.P., 17950 PRESTON ROAD, SUITE 1000, DALLAS, TX, 75252, US

(21) Appl. No.: 12/212,498

(22) Filed: Sep. 17, 2008

(51) Int. Cl. H01L 23/538; H01L 21/60

(52) U.S. Cl. 257/621; 438/109; 257/777; 257/E23.169; 257/E21.509

(57) ABSTRACT

Structures and methods of forming stacked chips are disclosed. In one embodiment, a first chip is disposed over a second chip, a top surface of the first and the second chip includes active circuitry. A first through substrate via is disposed within the first chip, the first through substrate via includes a protruding tip projecting below a bottom surface of the first chip, the bottom surface being opposite the top surface. A second through substrate via is disposed on the second chip, the second through substrate via including an opening, wherein the first protruding tip of the first chip is disposed within the opening of the second chip.

### TECHNICAL FIELD

The present invention relates generally to stacked semiconductor chips and, more particularly, to stacked chips with through substrate vias.

### BACKGROUND

One of the goals in the fabrication of electronic components is to minimize the size of various components. For example, it is desirable that handheld devices such as cellular telephones and personal digital assistants (PDAs) be as small as possible. To achieve this goal, the semiconductor circuits that are included within the devices should be as small as possible. One way of making these circuits smaller is to stack the chips that carry the circuits.

A number of ways of interconnecting the chips within the stack are known. For example, bond pads formed at the surface of each chip can be wire-bonded, either to a common substrate or to other chips in the stack. Another example is a so-called micro-bump 3D package, where each chip includes a number of micro-bumps that are routed to a circuit board, e.g., along an outer edge of the chip.

Yet another way of interconnecting chips within the stack is to use through-vias. Through-vias extend through the substrate thereby electrically interconnecting circuits on various chips. Through-via interconnections can provide advantages in terms of interconnect density compared to other technologies. However, introduction of such interconnects may introduce additional challenges.

The integration of chips in 3D brings-forth a number of new challenges that need to be addressed. One of the challenges arises due to misalignment of the through substrate vias between the stacked chips. Furthermore, as new materials and advanced material stacks are used, chip bow and the change of the chip bow with increased temperature can result in problems while stacking. These challenges increase dramatically as the diameter of the through substrate vias decrease. Hence, what is needed in the art are improved structures and methods of producing structures for 3D chip integration that overcome these challenges.

### SUMMARY OF THE INVENTION

These, and other problems, are generally solved or circumvented, and technical advantages are generally achieved, by preferred embodiments of the present invention which include structures and methods of forming stacked chips using through substrate vias.

Embodiments of the invention include structures and methods of forming stacked chips. In accordance with an embodiment of the present invention, a stacked chip comprises a first chip disposed over a second chip and a top surface of the first and the second chip, which includes active circuitry. A first through substrate via is disposed within the first chip. The first through substrate via includes a protruding tip projecting below a bottom surface of the first chip, the bottom surface being opposite the top surface. A second through substrate via is disposed on the second chip. The second through substrate via includes an opening, wherein the first protruding tip of the first chip is disposed within the opening of the second chip.

The foregoing has outlined rather broadly the features of an embodiment of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1, which includes FIGS. 1a and 1b, illustrates a stacked chip comprising through substrate vias, in accordance with an embodiment of the invention;

FIG. 2, which includes FIGS. 2a and 2b, illustrates a stacked chip comprising through substrate vias, in accordance with an embodiment of the invention;

FIG. 3, which includes FIGS. 3a-3e, illustrates a magnified bottom view of a protruding tip of a through substrate via used in fabricating a stacked chip, in accordance with an embodiment of the invention;

FIG. 4, which includes FIGS. 4a and 4b, illustrates a bottom view of a chip before being stacked to form a stacked chip, in accordance with an embodiment of the invention;

FIG. 5, which includes FIGS. 5a-5h, illustrates a stacked chip forming a through substrate via in various stages of processing, in accordance with an embodiment of the invention;

FIG. 6 illustrates a flow chart of the process steps used in the fabrication of the stacked chip as illustrated in FIG. 5;

FIG. 7, which includes FIGS. 7a-7f, illustrates a stacked chip forming a through substrate via in various stages of processing, in accordance with an embodiment of the invention;

FIG. 8 illustrates a flow chart of the process steps used in the fabrication of the stacked chip as illustrated in FIG. 7;

FIG. 9, which includes FIGS. 9a-9c, illustrates a stacked chip forming a through substrate via in various stages of processing, in accordance with an embodiment of the invention;

FIG. 10 illustrates a flow chart of the process steps used in the fabrication of the stacked chip as illustrated in FIG. 9;

FIG. 11, which includes FIGS. 11a-11d, illustrates a stacked chip forming a through substrate via in various stages of processing, in accordance with an embodiment of the invention; and

FIG. 12 illustrates a flow chart of the process steps used in the fabrication of the stacked chip as illustrated in FIG. 11.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely through substrate vias coupling stacked chips. The invention may also be applied, however, to other semiconductor components comprising, for example, multiple chips with multiple through substrate vias. One of ordinary skill in the art will be able to recognize further examples as well.

Embodiments of the present invention utilize through substrate vias to create 3D chip packages. Stacking chips on top of one another provides a means to achieve density, increased functionality and/or additional performance. One way to realize the full benefits of chip stacking is to connect the chips using deep, or through substrate vias. These vias extend from the active circuitry at one face of the chip to a bottom surface of the chip.

One of the key problems associated with stacking such devices arises from yield loss due to misalignment between the through substrate vias during the stacking. Misalignment between the chips results in sub-optimal or no contact between the stacked chips. This problem is further alleviated with scaling that reduces the minimum pitch of through substrate vias (distance between adjacent TSV), a substantial reduction in diameter of the through substrate vias. Misalignment can also arise due to heating or soldering during the soldering process. One way to avoid such a mismatch is to create bond pads disposed on the surface of the through substrate via for contacting. However, such bond pads consume area and limit the number of through substrate vias (or limit the density of TSVs) that can be used. Further, to minimize misalignment, identical chips are fabricated resulting in a narrow processing window during manufacturing.

In various embodiments, the present invention overcomes these problems by forming a through substrate via that is self-centering and self-aligning provided the through substrate via comprises a tip that projects out of the chip and a gap designed to fit the tip. In various embodiments, the projecting tip fits into a corresponding gap of an adjacent chip.

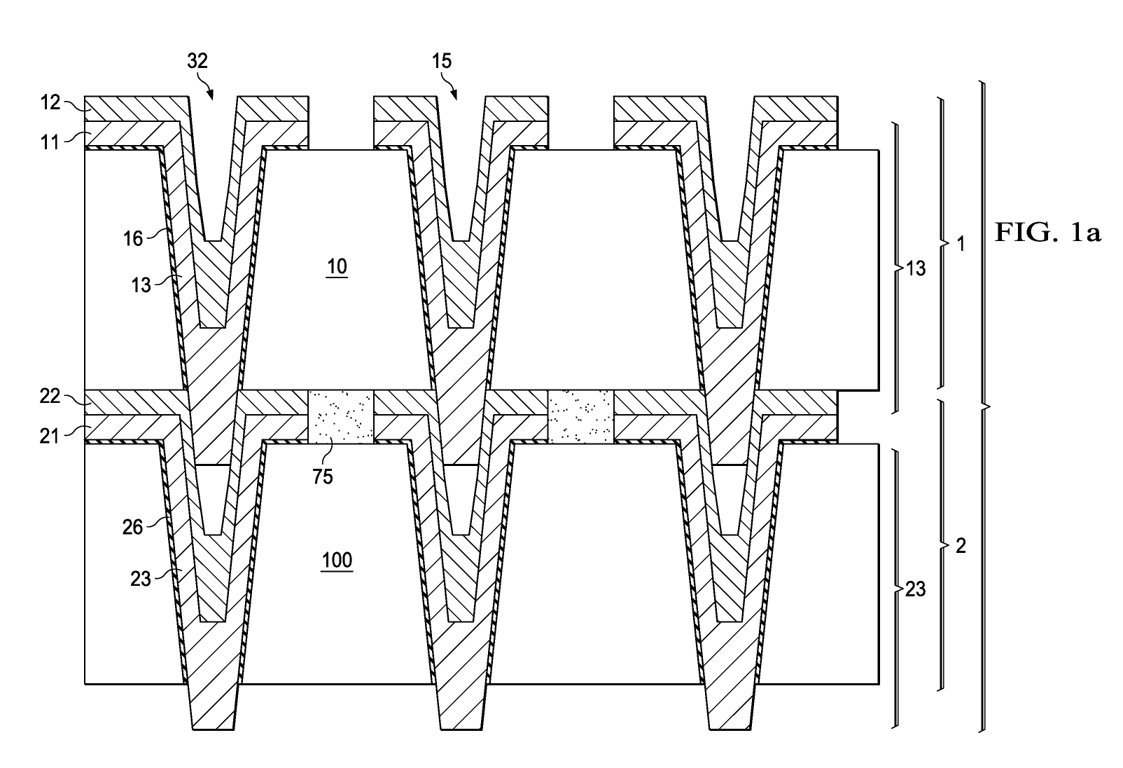

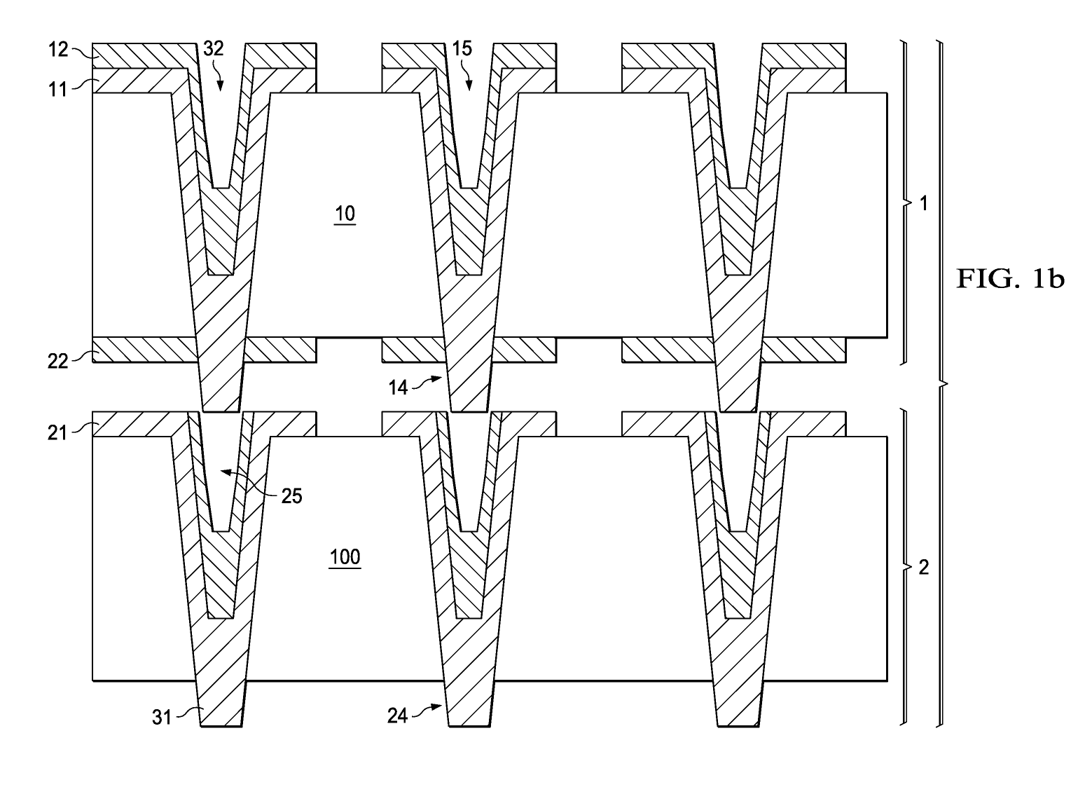

FIG. 1, which includes FIGS. 1a and 1b, illustrates an embodiment comprising a stacked chip. FIG. 1a illustrates two chips stacked together, whereas FIG. 1b illustrates the chips separated prior to stacking. The stacked chip comprises a first chip 1 disposed over a second chip 2. The first and second chips 1 and 2 are any type of semiconductor chips. Examples of the first and the second chips 1 and 2 include logic chips such as processors, analog and/or RF components, non-volatile memory, volatile memory, or an integrated system on chip. The first and the second chips 1 and 2 are formed in a first substrate 10 and a second substrate 100, respectively. A first through substrate via 13 is disposed in the first substrate 10, and a second through substrate via 23 is disposed in the second substrate 100. The first through substrate via 13 is disposed above the second through substrate via 23.

Referring to FIG. 1b, the first through substrate via 13 comprises a first protruding tip 14 and a first gap 15, similarly the second through substrate via 23 comprises a second protruding tip 24 and a second gap 25. In various embodiments, the first protruding tip 14 and the second protruding tip 24 are identical, while the first and the second gaps 15 and 25 are identical.

As illustrated in FIG. 1a, the first projecting tip 31 is disposed inside the second through substrate via 23 in the second gap 25. The first through substrate via 13 comprises a first outer conductive layer 11 and a first inner conductive layer 12. The first inner conductive layer 12 is disposed over the first outer conductive layer 11. The first outer conductive layer 11 is insulated from the first substrate 10 by a first dielectric liner 16.

Similarly, the second through substrate via 23 comprises a second outer conductive layer 21, and a second inner conductive layer 22 disposed on the second outer conductive layer 21. The second outer conductive layer 21 is insulated from the second substrate 100 by a second dielectric liner 26.

In various embodiments, the first protruding tip 14 of the first chip 1 is designed to be fit into the second gap 25 of the second chip 2. Similarly, the design of the second gap 25 is optimized to facilitate the fitting of the first protruding tip 14 into the second gap 25. In various embodiments, the first and second protruding tips 14 and 24 project about 100 nm to about 5 um from the surface of the chip, and about 1 um in one embodiment.

The first and second outer conductive layers 11 and 21 comprise a material comprising copper, aluminum, platinum, gold, and combinations thereof. In some embodiments, the first and the second outer conductive layers 11 and 21 comprise other materials such as doped polysilicon, metal silicides, or intermetallics such as TiN or TaN.

The first and the second inner conductive layers 12 and 22 comprise a material that additionally bonds with the first and the second outer conductive layers 11 and 21 upon heating. For example, in one embodiment, the first and the second inner conductive layers 12 and 22 comprise a material that mixes with the first and the second outer conductive layers 11 and 21. Examples of the first and second inner conductive layers 12 and 22 include metals used as solders that form eutectic compounds upon intermixing with the first and the second outer conductive layer 11 and 21. In one embodiment, the first and the second outer conductive layers 11 and 21 comprise copper, and the corresponding first and the second inner conductive layers 12 and 21 comprise tin.

In various embodiments, the first and the second chips 1 and 2 are also bonded by adhesive layers 75 for enhanced support. The additional support provided by the adhesive layer 75 minimizes stress and supports alignment and stability during the fabrication and usage.

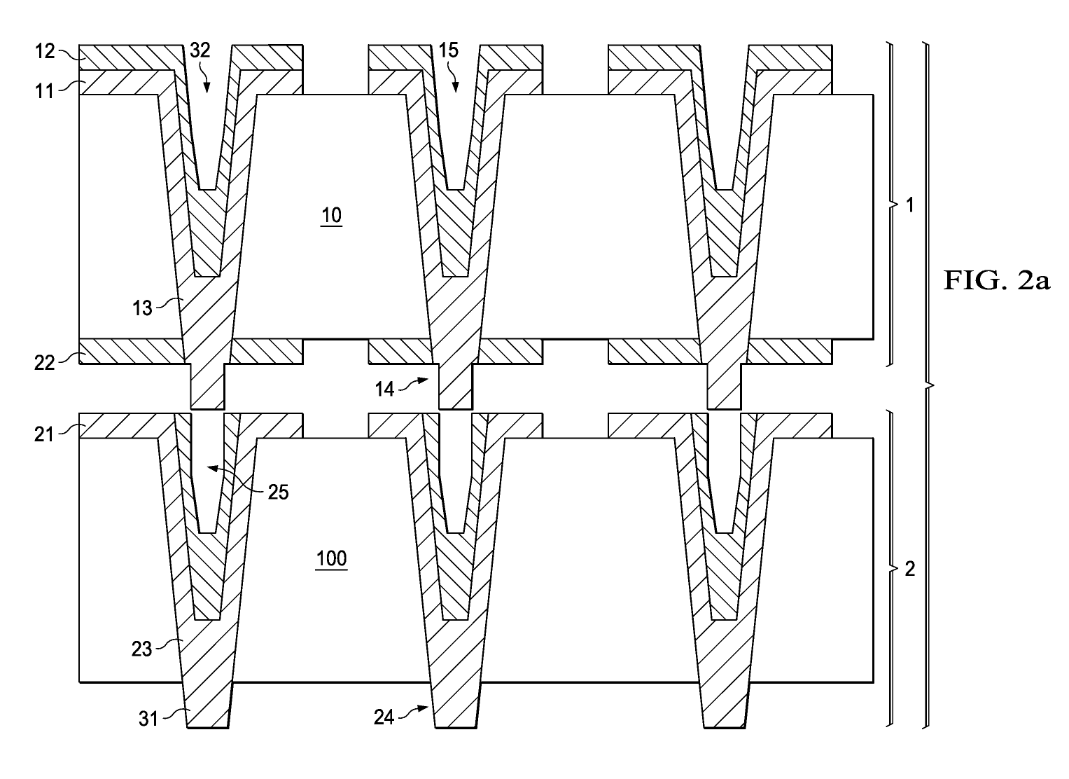

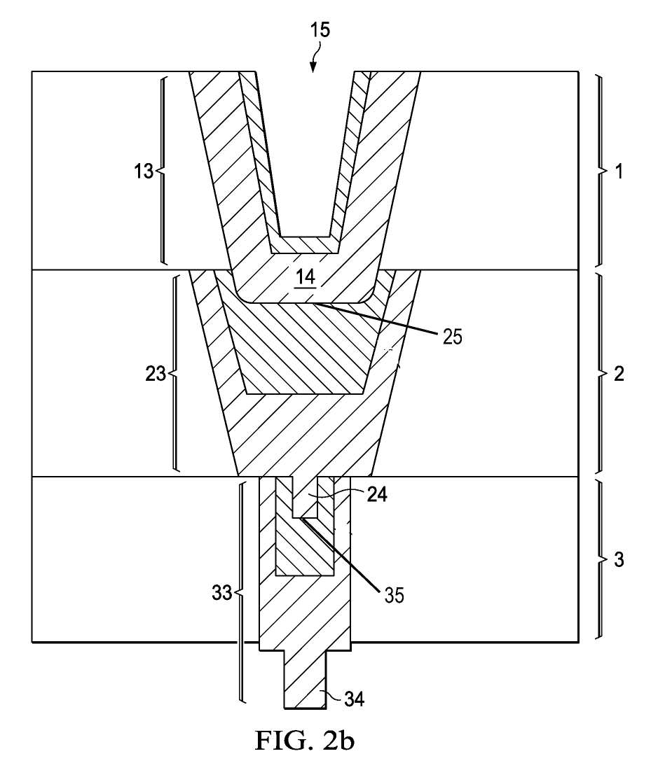

FIG. 2, which includes FIGS. 2a and 2b, illustrates structural embodiments of the stacked chip.

Referring to FIG. 2a, the first chip 1 comprises first through substrate vias 13. Further the first through substrate vias 13 comprise a first protruding tip 14 as in the prior embodiment. However, unlike the prior embodiment, the first through substrate vias 13 are shaped differently. In particular, in one embodiment, the first protruding tip 14 does not comprise a taper. Instead the sidewalls of the first protruding tip 14 are parallel to each other. Accordingly, the second gap 25 comprises substantially vertical sidewalls to correctly fit the first protruding tip 14.

FIG. 2b illustrates an embodiment describing three stacked chips comprising through substrate vias of different shapes and sizes. A first chip 1 is disposed on a second chip 2, and the second chip 2 is disposed on the third chip 3. A first through substrate via 13 is disposed in the first chip 1, a second through substrate via 23 is disposed in the second chip 2, and a third through substrate via 33 is disposed inside the third chip 3.

Referring to FIG. 2b, the first through substrate via 13 comprises a first protruding tip 14 and a first gap 15, the second through substrate via 23 comprises a second protruding tip 24 and a second gap 25, and the third through substrate via 33 comprises a third protruding tip 34 and a third gap 35. As in the prior embodiments, the first protruding tip 14 fits into the second gap 25. Similarly, the second protruding tip 24 fits into the third gap 35. However, unlike the prior embodiments, the first, the second and the third through substrate vias 13, 23, and 33 comprise different shapes and configurations. Similarly, as illustrated in FIG. 2b, the first, the second and the third chips 1, 2 and 3 comprise different sizes. Although the first, the second and the third through substrate vias 13, 23, and 33 comprise different shapes and configurations, they each comprise a protruding tip that fits into a corresponding gap in the underlying chip. For example, the tapered first protruding tip 14 fits into a second gap 25 although the first and the second through substrate vias 13 and 23 comprise different dimensions. In the illustrated embodiment, the second through substrate via 23 comprises an average width that is smaller than an average width of a first through substrate via 13. Similarly, the second through substrate via 23 comprises an average width that is larger than an average width of a third through substrate via 33. The second protruding tip 24 comprises parallel sidewalls unlike the first protruding tip 14. Accordingly, the third gap 35 and the third substrate via 33 comprise substantially parallel sidewalls unlike, for example, the tapered first through substrate via 13.

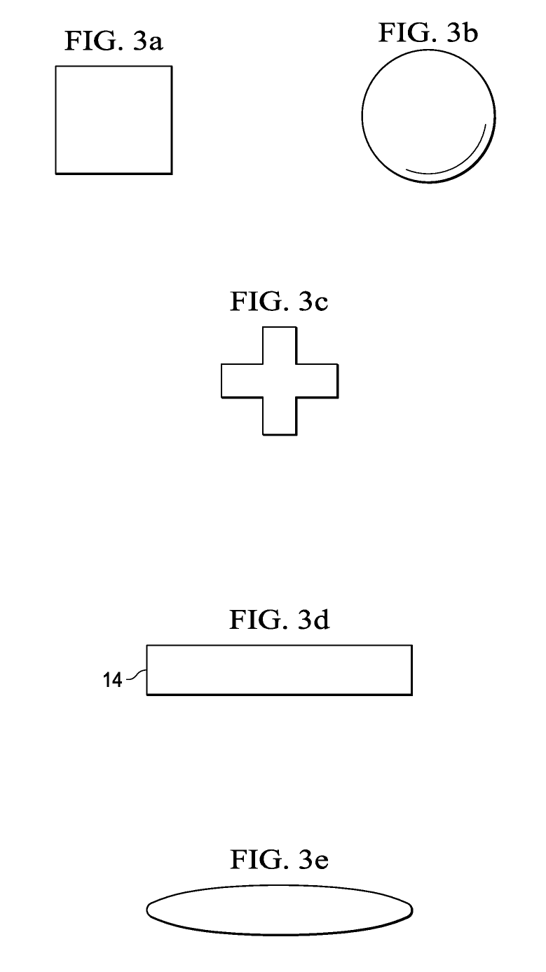

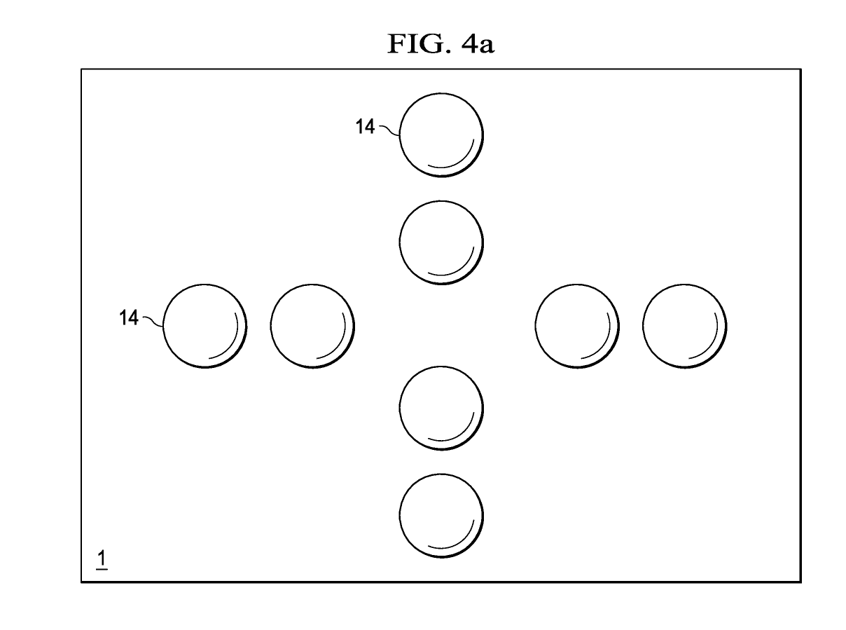

FIG. 3, which includes FIGS. 3a-3e, illustrates a bottom view of a protruding tip of a through substrate via in various embodiments of the invention.

In various embodiments, the through substrate via of a chip comprises a shape that is designed to couple or self-align with a corresponding gap of a further chip during the stacking process. As illustrated, in various embodiments, the protruding tip of the through substrate via comprises a square (FIG. 3a), a circle (FIG. 3b), elongated shapes such as a rectangle (FIG. 3d), and an oval (FIG. 3e). In some embodiments, the protruding tip is plus shaped (FIG. 3c) to promote improved alignment and coupling between the stacked chips.

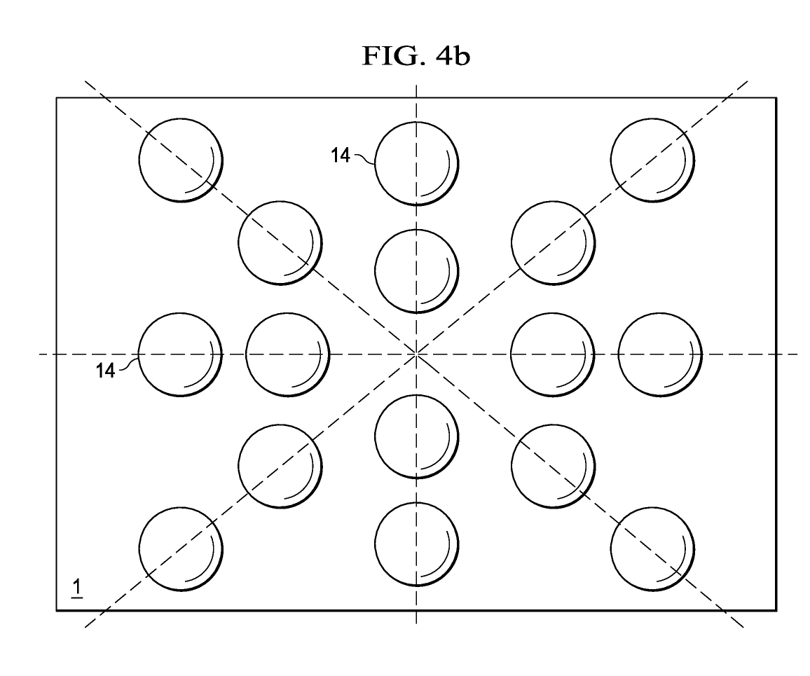

FIG. 4, which includes FIGS. 4a and 4b, illustrates arrangements of the through substrate vias to promote alignment and coupling between the stacked chips. FIG. 4 illustrates a bottom view of the protruding tips of the through substrate vias on the chip.

As the number of through substrate vias increases, while the diameter of the individual through substrate vias decreases, aligning the vias correctly poses a significant challenge. For example, a first via on an overlying chip may be get incorrectly aligned to a second via on the underlying chip instead of to a third via on the underlying chip. In various embodiments, the through substrate vias are designed not only to minimize misalignment with a particular via, but to also minimize contact errors by coupling to a wrong via or contact.

Referring to FIGS. 4a and 4b, the through substrate vias (for example, first through substrate vias 13 of FIG. 1) are arranged to minimize errors in alignments. For example, by arranging the through substrate vias along only perpendicular lines, simultaneous self-aligning of all the through substrate vias on the chip is promoted.

In a further embodiment illustrated in FIG. 4b, the through substrate vias are arranged radially in the chip. This minimizes misalignment errors arising from a particular through substrate via on the overlying chip coupling with an incorrect through substrate via on the underlying chip. In various embodiments, other complicated patterns of the through substrate vias leveraging this scheme are used.

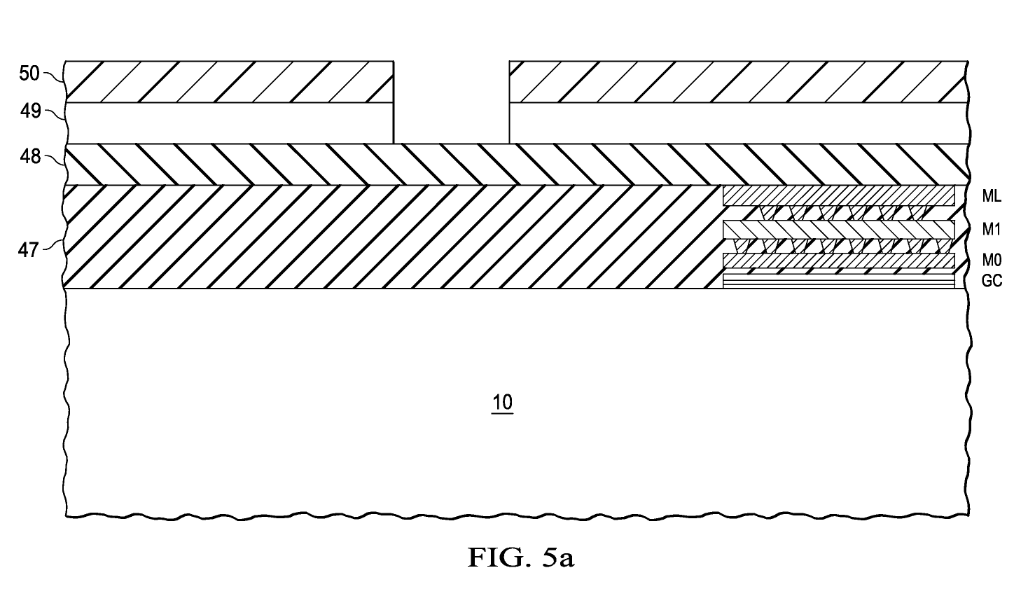

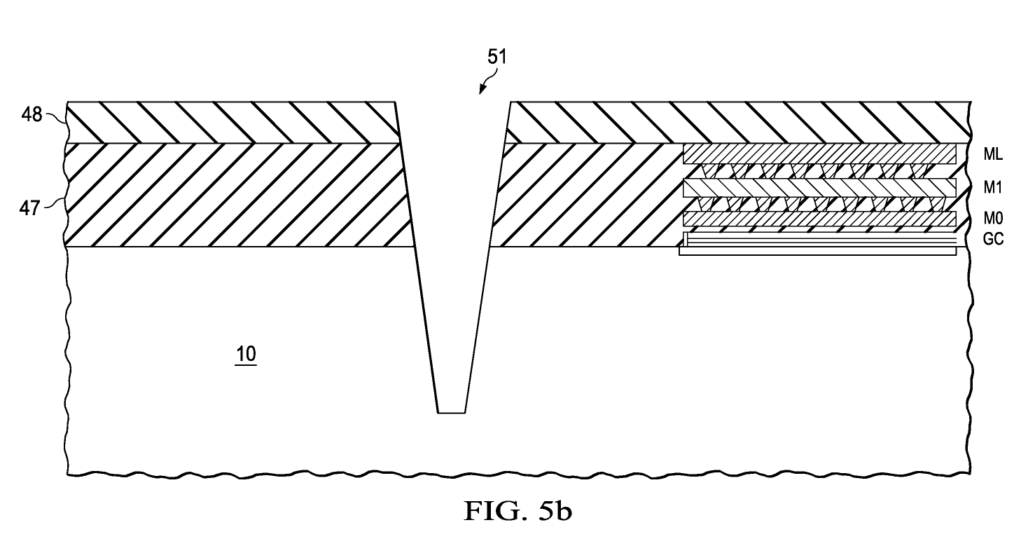

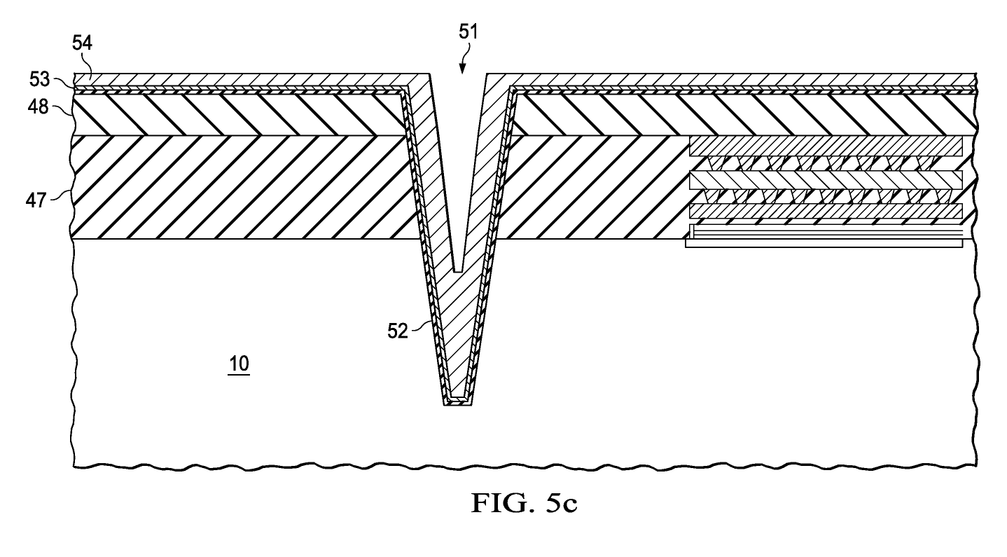

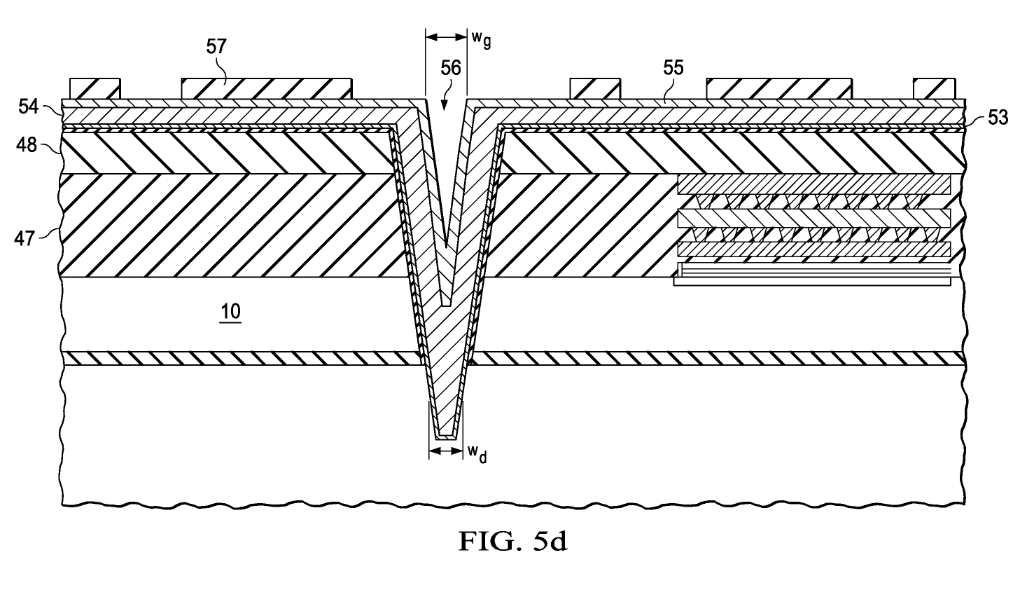

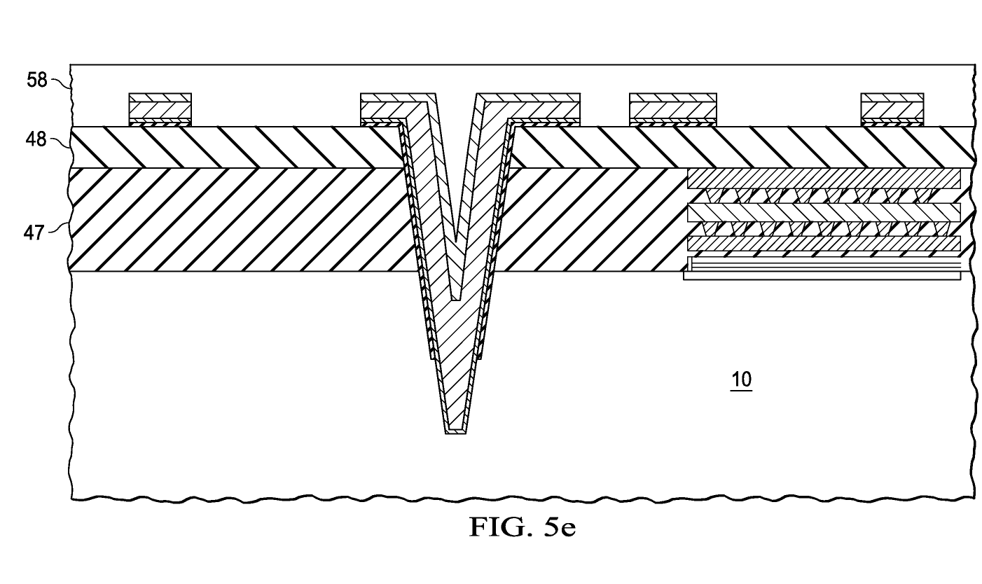

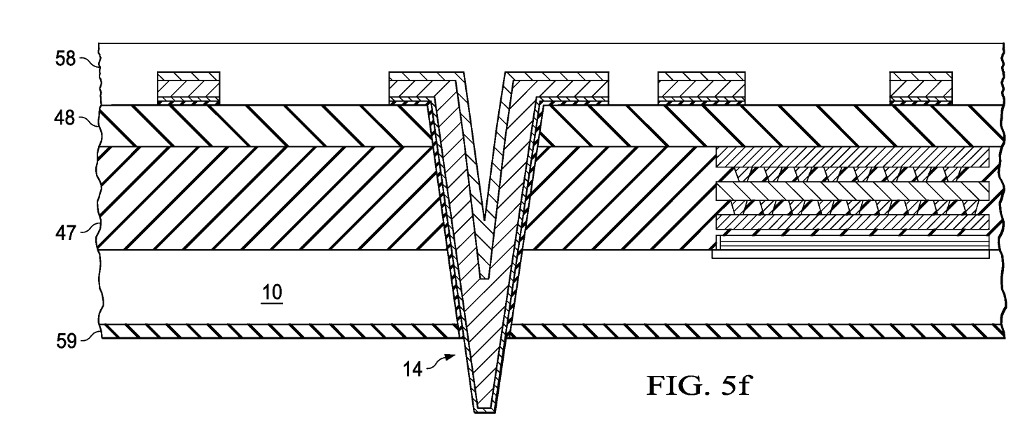

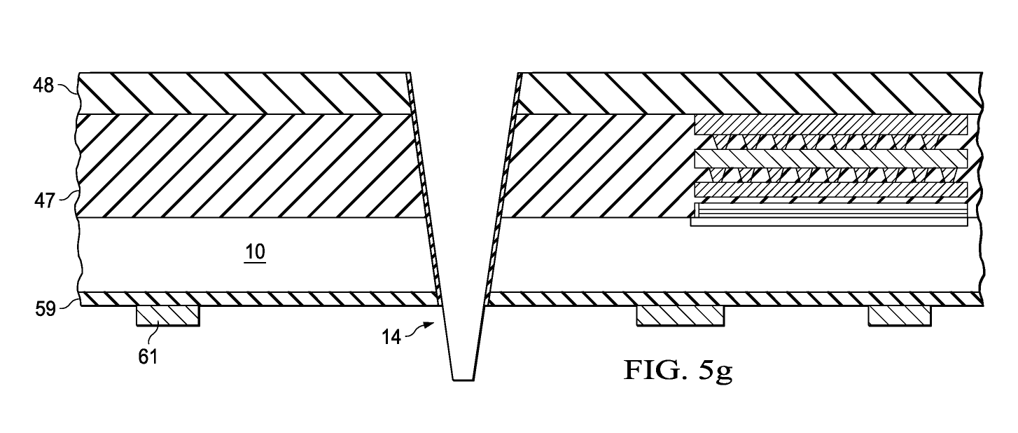

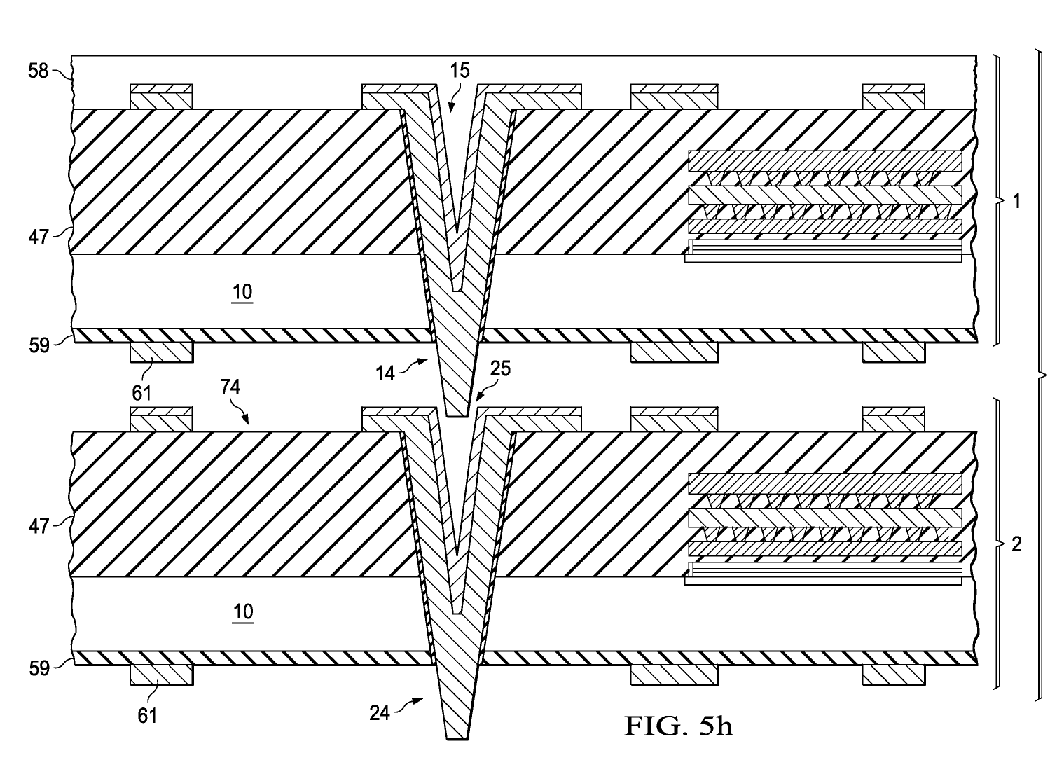

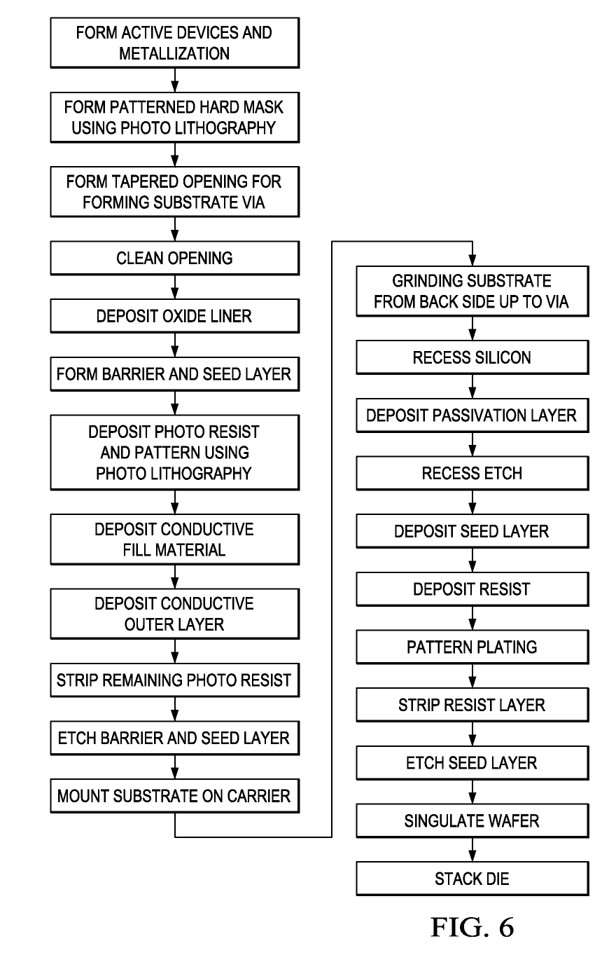

FIG. 5, along with the flow chart of FIG. 6, illustrates an embodiment of the invention describing steps during fabrication of the stacked chips.

The method described illustrates forming the first protruding tip 14 and first gap 15 of a first chip 1 (as illustrated in FIG. 1a), but identical processing can be adopted to form the second chip comprising the second protruding tip 24 and the second gap 25 of the second chip 2.

Referring to FIG. 5a, and as illustrated in flow chart of FIG. 6, device regions are formed near a top surface of a first substrate 10 during front end processing. The first substrate 10 is typically a semiconductor wafer. The device regions, or active circuitry, can include transistors, resistors, capacitors, inductors or other components used to form integrated circuits. For example, active areas that include transistors (e.g., CMOS transistors) are formed separate from one another by isolation regions, e.g., shallow trench isolation.

Next, metallization is formed over the device regions to electrically contact and interconnect the device regions. The metallization and active circuitry together form a completed functional integrated circuit. In other words, the electrical functions of the chip can be performed by the interconnected active circuitry. In logic devices, the metallization may include many layers, e.g., nine or more, of copper. In memory devices, such as DRAMs, the number of metal levels may be less and may be aluminum.

The components formed during the front-end processing are interconnected by back end of line (BEOL) processing. During this process, contacts are made to the semiconductor body and are interconnected using metal lines and vias. As discussed above, modern integrated circuits incorporate many layers of vertically stacked metal lines and vias (multilevel metallization) that interconnect the various components in the chip. In FIG. 5a, only three levels of metal (first metal level M0, and a second metal level M1, and the last metal level ML) are illustrated above the gate level. The metal levels are formed in an insulating layer 47. Although illustrated as a single layer, the insulating layer 47 comprises multiple layers. In various embodiments, each metal level is formed after forming a portion of the insulating layer 47. In various embodiments, the insulating layer 47 comprises multiple layers comprising different dielectric materials.

The insulating layer 47 comprises insulating materials typically used in semiconductor manufacturing for inter-level dielectric (ILD) layers, such as SiO2, tetra ethyl oxysilane (TEOS), fluorinated TEOS (FTEOS), doped glass (BPSG, PSG, BSG), organo silicate glass (OSG), fluorinated silicate glass (FSG), spin-on glass (SOG), SiN, SiON, or low k insulating materials, e.g., having a dielectric constant of about 4 or less, or combinations, or multiple layers thereof, as examples, although alternatively, the insulating layer 47 may comprise other materials. The ILD may also comprise dense SiCOH, or a porous dielectric having a k value of about 3 or lower, as examples. The ILD may also comprise an ultra-low k (ULK) material having a k value of about 2.3 or lower, for example. The ILD may comprise a thickness of about 500 nm or less, for example, although alternatively, the ILD may comprise other dimensions.

A passivation layer 48 is deposited over the last metal level ML. The passivation layer 48 comprises oxide in one embodiment, although in other embodiments other suitable materials are used. The passivation layer 48 can include more than one layer of material, such as silicon oxide, silicon nitride or silicon oxynitride or polyimide, as just a few examples. The passivation layer 48 includes openings to expose the contact areas.

A hard mask layer 49 is optionally deposited over the passivation layer 48. The hard mask layer 49 protects the top surface of the passivation layer 48 during the through trench etch. The hard mask layer 49 is chosen based on the selectivity of the through trench etch process. Through trench etch processes using a high density plasma with a fluorine chemistry typically utilize a SiO2 hard mask layer 49. The hard mask layer 49 comprises a single layer in one embodiment. In other embodiments, a bilayer or tri-layer hard mask layer can be used. A photo resist layer 50 is deposited over the hard mask layer 49. Using photo lithography, the photo resist layer 50 is exposed, developed, and patterned. Using the patterned photo resist layer 50, the hard mask layer 49 is patterned. The hard mask layer 49 may be skipped if the photo resist layer 50 comprises sufficient selectivity such that the patterned photo resist layer 50 can be used as a mask.

Referring to FIG. 5b, a through substrate opening 51 is formed. Although, only one through substrate opening is illustrated, a chip may comprise more than one through substrate opening.

The through substrate opening 51 is formed using a resist only process, a Bosch Process, or by depositing a hard mask layer and etching the substrate 10 using a vertical reactive ion etch. In one embodiment, only a resist mask is used. If the resist budget is not sufficient, the use of a hard mask and vertical reactive ion etch may be preferred if a smooth sidewall is required. However, this integration scheme requires the removal of remaining hard mask residues. Hence, in some embodiments a Bosch process that uses resist only and a deposition-etch process sequence which overcomes these limitations, but produces sidewalls that are scalloped, can be applied.

Referring to FIG. 5c, liners comprising an insulating layer, diffusion barrier for subsequent conductive materials, and seed layers are deposited over the through substrate opening 51. A sidewall dielectric layer 52 is deposited over the sidewalls and bottom surface of the through substrate opening 51. The sidewall dielectric layer 52 electrically isolates the conductive material in the through substrate via from active devices on the first substrate 10. The sidewall dielectric layer 52 is deposited conformally over the exposed surfaces of the through substrate opening 51. The sidewall dielectric layer 52 may be deposited by a suitable low temperature process such as plasma enhanced CVD and/or organic vapor phase deposition. In some embodiments, the sidewall dielectric layer 52 is anisotropically etched forming a sidewall on the through substrate opening 51. In the embodiment described here, the sidewall dielectric layer 52 is removed from the bottom of the through substrate opening 51 after thinning of the first substrate 10.

A trench metal liner 53 is deposited over the sidewall dielectric layer 52 prior to filling the through substrate opening 51 with a conductive material. The trench metal liner 53 is conformal, and in one embodiment comprises a single layer of Ta, TaN, WN, WSi, TiN, and/or Ru as examples. In various embodiments, the trench metal liner 53 is used as a barrier layer for preventing metal from diffusing into the underlying first substrate 10 and the sidewall dielectric layer 52. The trench metal liner 53 is deposited, for example, using sputtering processes. For high aspect ratio features, highly directional processes such as collimated sputtering techniques or CVD may be used.

In various embodiments, the trench metal liner 53 comprises multiple layers. In one embodiment, the trench metal liner 53 comprises a seed layer of copper over the diffusion barrier layer. This seed layer is deposited conformally over the barrier layer, using for example, a metal-organic CVD (MOCVD) process.

As illustrated in FIG. 5d, patterns are formed using photo lithography to open areas for forming conductive vias and metal lines for connecting to the conductive vias. A photo resist layer 57 is deposited over the trench metal liner 53 and patterned using photo lithography.

Referring to FIG. 5d, a conductive fill material 54 is then deposited using, for example, an electroplating process. The conductive fill material 54 is partially filled leaving a gap. In one embodiment, the conductive fill material 54 comprises copper. In other embodiments, the conductive fill material 54 comprises aluminum, tantalum, ruthenium, platinum, nickel, silver, gold, tungsten, tin, lead, or combinations thereof. If the conductive fill material 54 comprises tungsten, a bi-layer seed layer comprising CVD titanium nitride and silicon doped tungsten are used. Similarly, in some embodiments, the conductive fill material 54 comprises doped poly-silicon or silicides.

A conductive outer layer 55 is deposited over the conductive fill material 54 while leaving an opening 56 within the through substrate opening 51. The conductive outer layer 55 covers the conductive fill material 54. In various embodiments, the opening 56 comprises a width wg that is substantially the same as the width wb of the bottom of the through substrate opening 51. Further, the opening 56 is designed to be about the same dimensions as the bottom of the through substrate opening 51.

The conductive outer layer 55 comprises a material that additionally bonds with the conductive fill material 54 upon heating. For example, in one embodiment, the conductive outer layer 55 comprises a material that mixes with the conductive fill material 54. Examples of the conductive outer layer 55 include metals used as solders that form eutectic compounds upon intermixing with the conductive fill material 54. In one embodiment, the conductive fill material 54 comprises copper, and the corresponding conductive outer layer 55 comprises tin. In one embodiment, the conductive fill material 54 comprising copper and the conductive outer layer 55 comprising tin, are electroplated.

In an alternate embodiment, the conductive fill material 54 is filled in to the through substrate opening 51 before patterning the photo resist layer 57. The conductive outer layer 55 is deposited over the conductive fill material 54 while leaving a gap within the through substrate opening 51. Subsequently, the photo resist layer 57 is deposited and patterned, exposing a region of conductive outer layer 55. The exposed conductive outer layer 55 is removed followed by the removal of the exposed conductive fill material 54. For example, if the conductive fill material 54 comprises copper, a suitable etchant comprising iron chloride may be used to remove the conductive fill material 54.

As illustrated in FIG. 5e, the photo resist layer 57 is stripped and underlying trench metal liner 53 is etched. The first substrate 10 is mounted onto a carrier 58 for handling in preparation of wafer thinning.

Referring to FIG. 5f, the first substrate 10 is thinned from the back surface and passivated. The first substrate 10 is thinned exposing a lower surface by grinding to a desired thickness. The typical thickness of the first substrate 10 after the thinning is about 3×104 nm to about 105 nm. In different embodiments, the thinning may also be performed chemically or by using a plasma etch. For example, a modified plasma etch may be used to thin the silicon wafer from the back side. Such techniques have the additional advantage of not damaging the front side.

The advantage of thinning the wafer (or chip, if the wafer has already been diced) is to shorten the length of the through-vias, which enhances the electric properties and speeds up the via etch processing and creates a via with relatively vertical sidewall.

The grinding exposes the back surface of the through substrate opening 51 filled with the conductive fill material 54. A subsequent silicon recess is removed to form a first protruding tip 14. The silicon recess is removed, for example, using a timed etch, to remove a thickness of the first substrate 10. In various embodiments, the thickness of the silicon recess (or height of the first protruding tip 14) is about 200 nm to about 2000 nm. The silicon etch is selected to be selective relative to the conductive fill material 54. For example, if conductive fill material 54 comprises copper, an etching chemistry comprising CF4 is chosen to selectively etch silicon without removing conductive fill material 54. However, an etching chemistry comprising CF6 has poor etch selectivity and etches both silicon and conductive fill material 54.

A back side insulating layer 59 is deposited, for example, by spin coating on the exposed back surface. In various embodiments, the back side insulating layer 59 is deposited up to about 1-2 um in thickness. The back side insulating layer 59 is recessed, for example, using a reactive ion etch or isotropic etch, forming the structure illustrated in FIG. 5h. The back side insulating layer 59 is recessed to about 200-800 nm in various embodiments.

As illustrated in FIG. 5g, back side pads 61 are formed. The back side pads 61 are conductive and may include redistribution lines coupled to other active circuitry. In some embodiments, the back side pads 61 comprise mechanical supports for the stacked chips. A conductive seed layer is deposited, followed by deposition of a photo resist layer. The photo resist layer is patterned using photo lithography to expose a layer of the underlying conductive seed layer. A conductive material is electroplated over the conductive seed layer forming the back side pads 61. In various embodiments, the back side pads 61 comprise copper.

Referring to FIG. 5h, a stacked chip is formed. The wafer comprising the first chip 1 is singulated and diced to form separate chips, although in some embodiments, the chips may be stacked without dicing the wafer. A second chip 2 is similarly formed comprising the second gap 25 and the second protruding tip 24. In one embodiment, the first and the second chips are formed on the same wafer. A suitable adhesive is dispensed between the first and the second chip 1 and 2 such that the adhesive does not flow into the first and the second gaps 15 and 25. The adhesive is dispensed into adhesive gaps 74 to avoid filling either the first or second gap 15 and 25. The first protruding tip 14 of the first chip is used to align and center the first chip 1 over the second chip 2 to form a stacked chip.

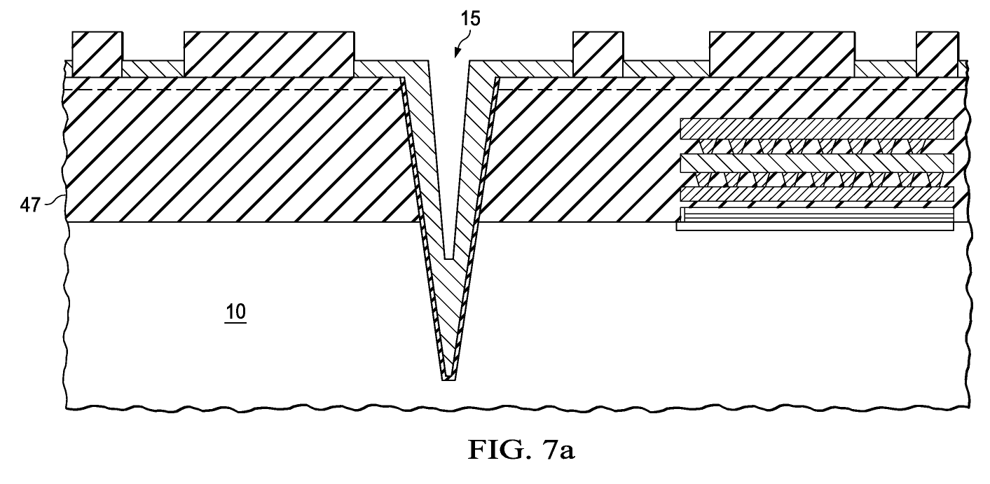

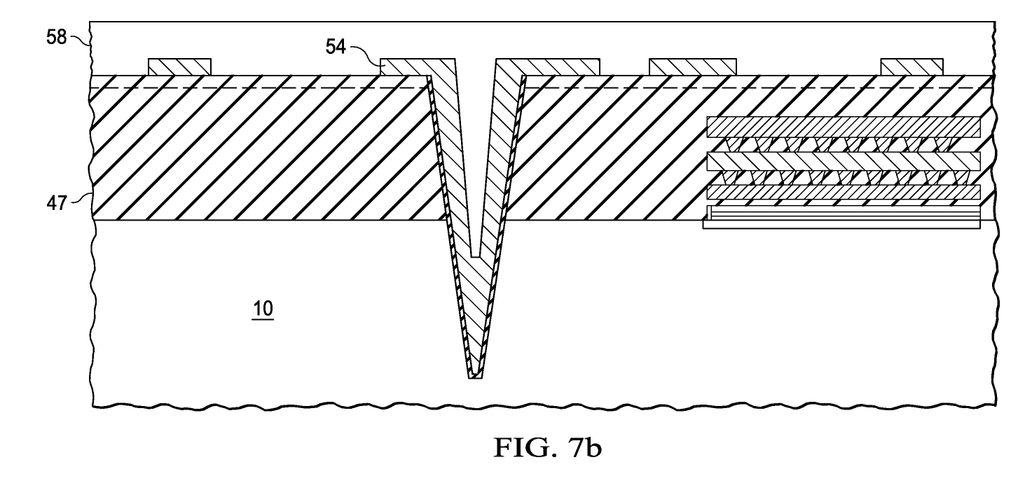

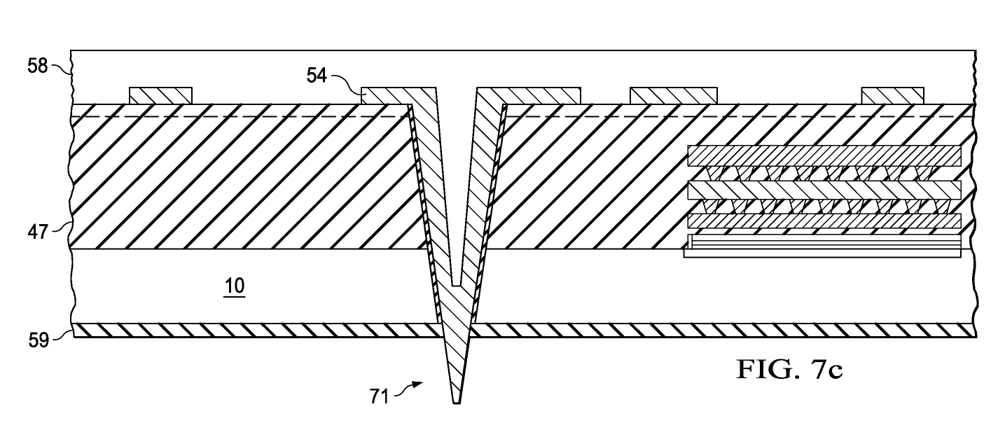

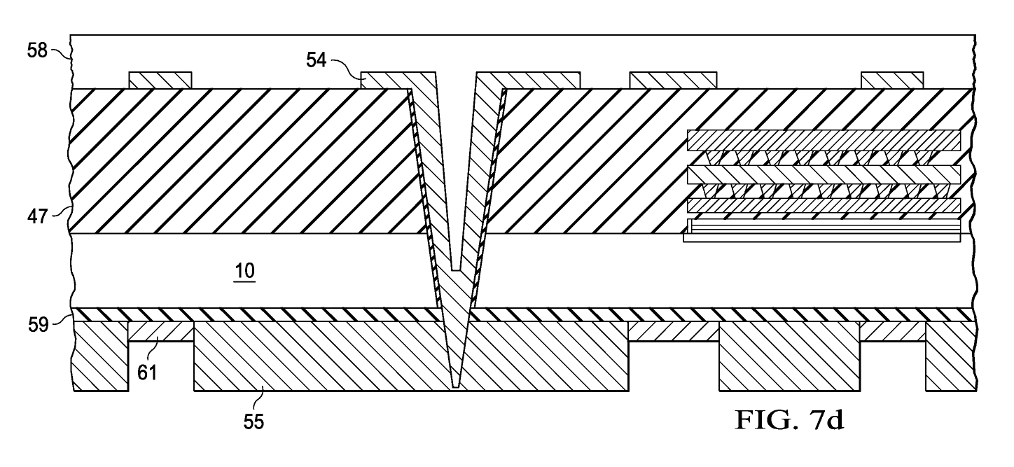

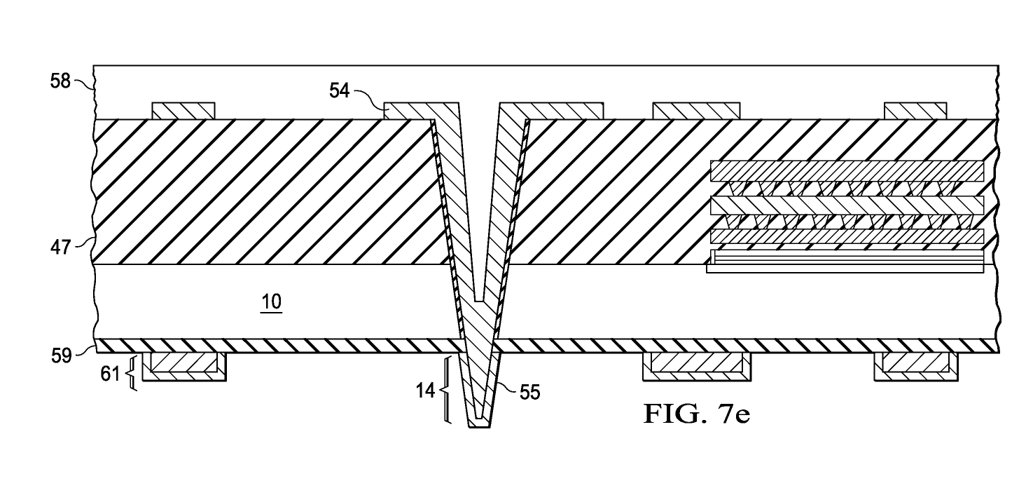

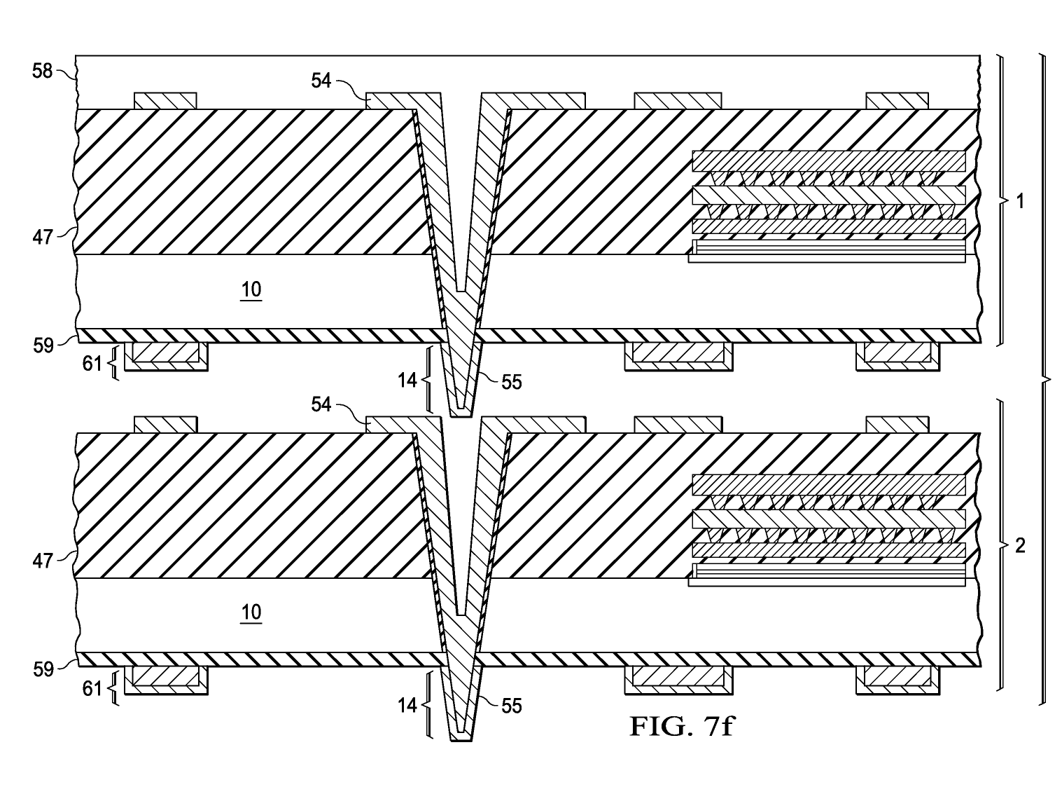

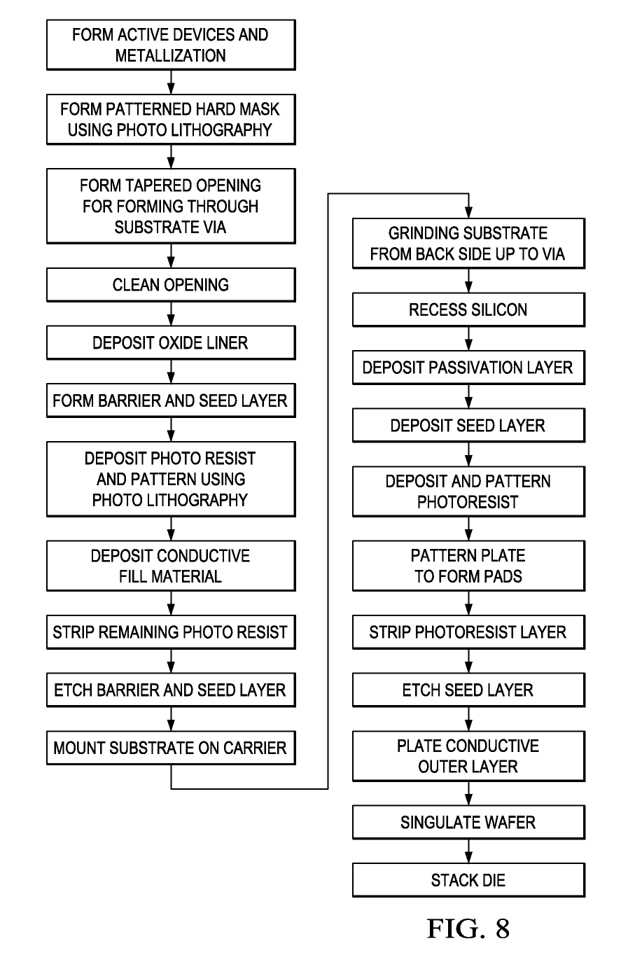

FIG. 7, along with the flow chart of FIG. 8, illustrates an embodiment of the invention describing steps during fabrication of the stacked chips.

The embodiment follows the prior embodiment as described with respect to FIGS. 7a-7c. As described in the prior embodiment with respect to FIG. 5f, a conductive fill material 54 is disposed in the through substrate opening 51. However, unlike FIG. 5d, a conductive outer layer is not formed, forming a larger opening, thereby forming a first gap 15.

The first substrate 10 is mounted onto a carrier 58 for handling in preparation of wafer thinning (FIG. 7b). The first substrate 10 is thinned from the back side and passivated, forming the first protruding part 71 (FIG. 7c). The first substrate 10 is thinned, exposing a lower surface by grinding to a desired thickness. As described with respect to FIG. 5g, back side pads 61 are formed as illustrated in FIG. 7d. Unlike the prior embodiments, a conductive outer layer 55 is deposited over the back side pads 61 and the first protruding part 71. The resulting first protruding tip 14 comprises the conductive fill material 54 covered with the conductive outer layer 55 (FIG. 7e).

The wafer is diced to form individual dies. As described in the prior embodiment with respect to FIG. 5h, a first chip 1 and a second chip 2 are stacked in this embodiment (FIG. 7f).

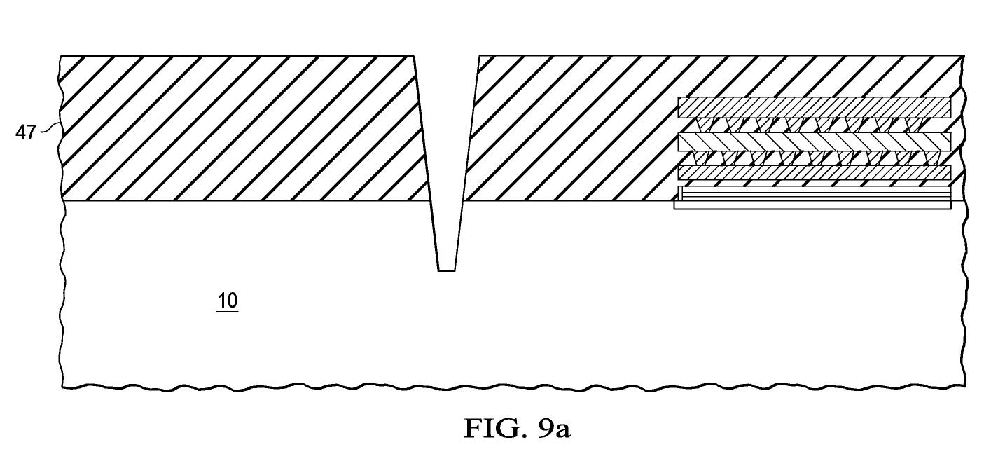

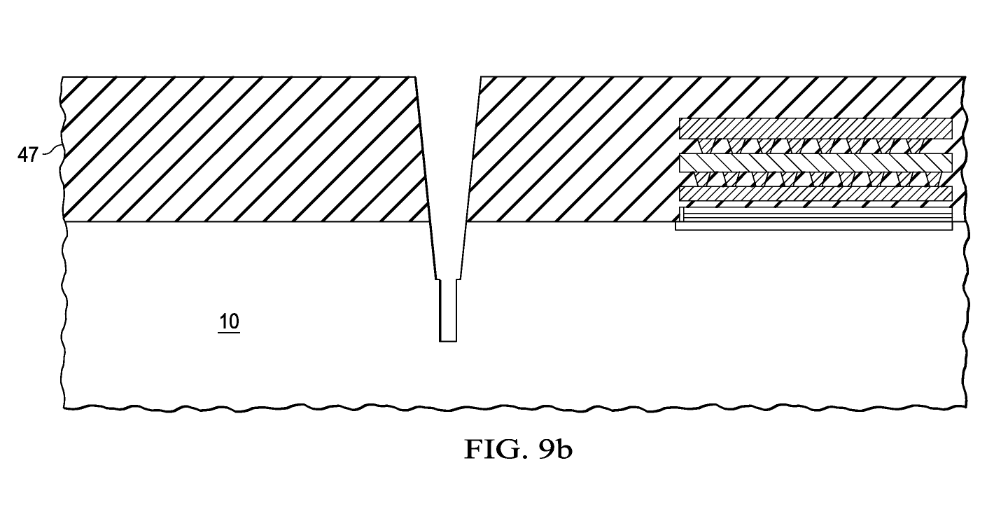

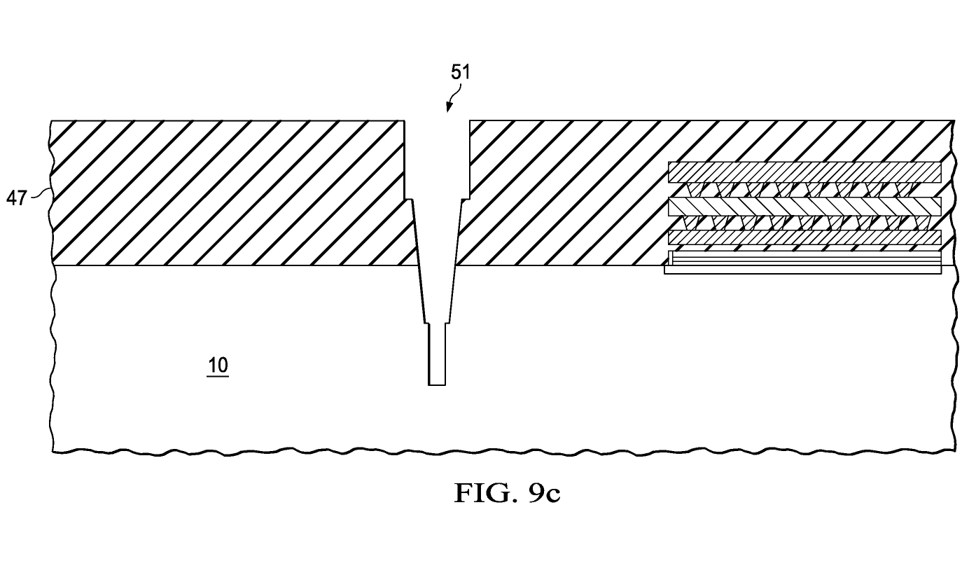

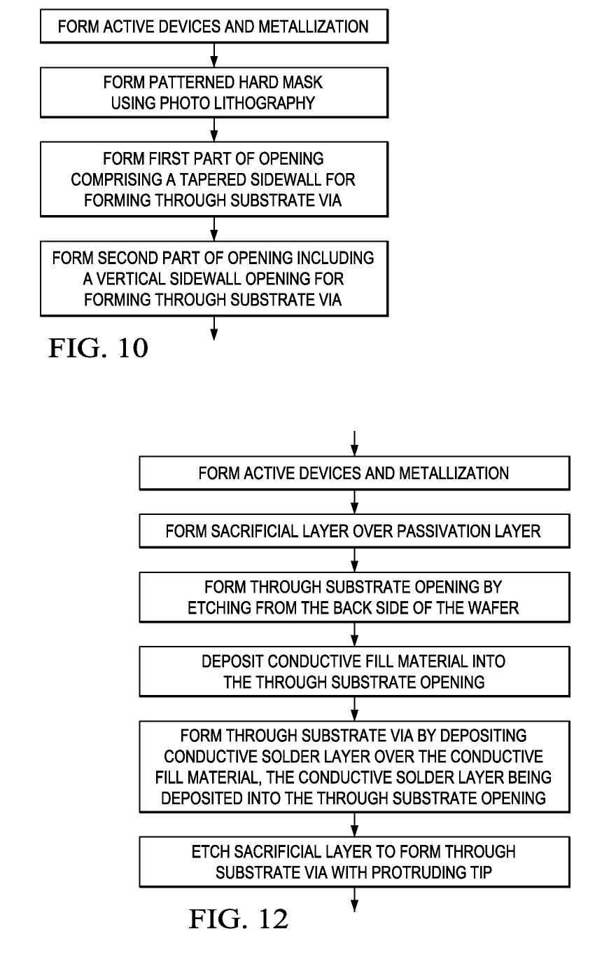

FIG. 9, which includes 9a-9c, along with the flow chart of FIG. 10, illustrates an embodiment of the invention describing steps during fabrication of the stacked chips.

In this embodiment, the through substrate opening 51 is designed differently. In various embodiments, the through substrate opening 51 is formed in at least two separate etch steps. In a first step of the etch process, a tapered opening is formed as illustrated in FIG. 9a. In a second step, as illustrated in FIG. 9b, a second deeper opening is formed, the second opening comprises substantially vertical sidewalls. FIG. 9c illustrates the through substrate opening 51 comprising two sections: a lower part comprising substantially vertical sidewalls, and an upper part comprising tapered sidewalls. Subsequent processing follows as described in previous embodiments.

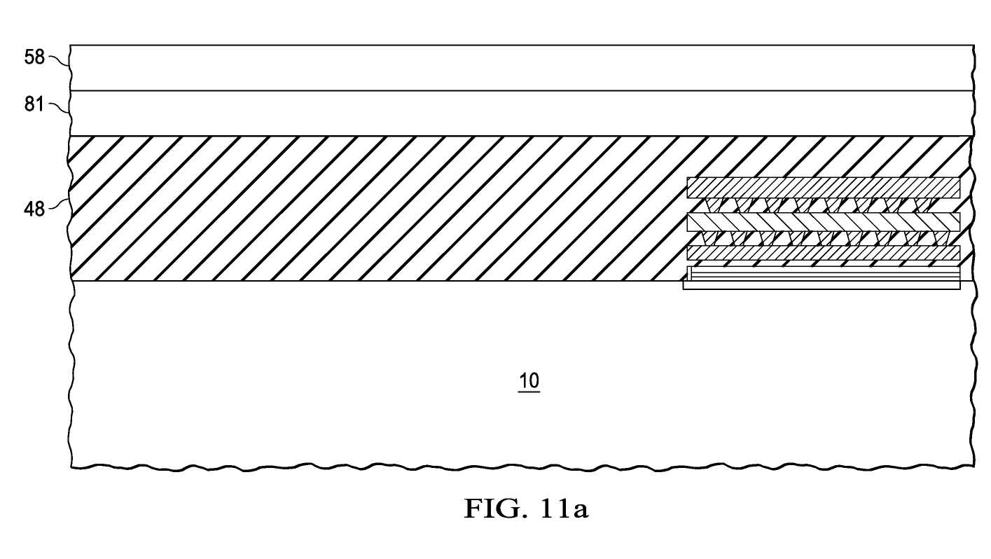

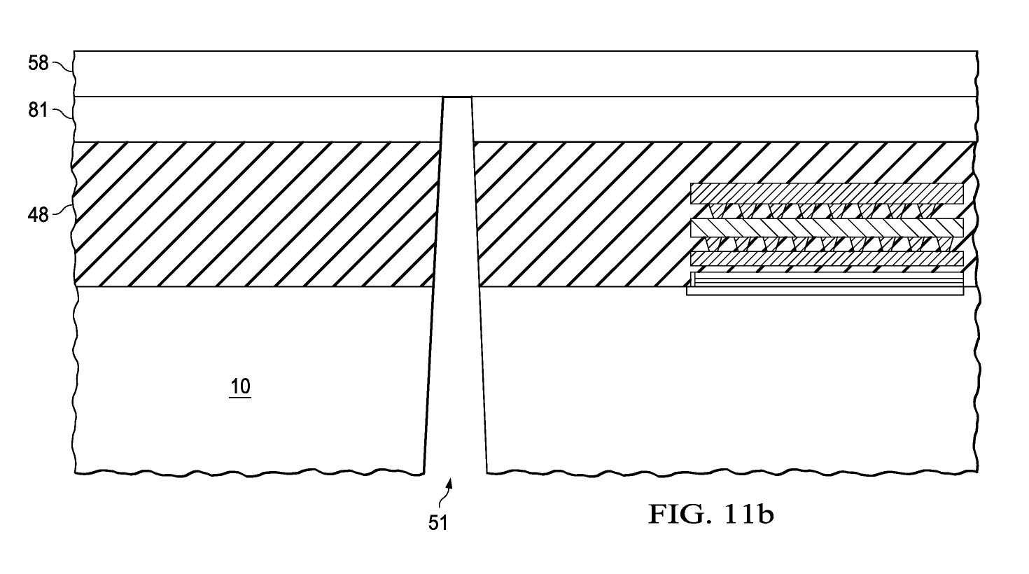

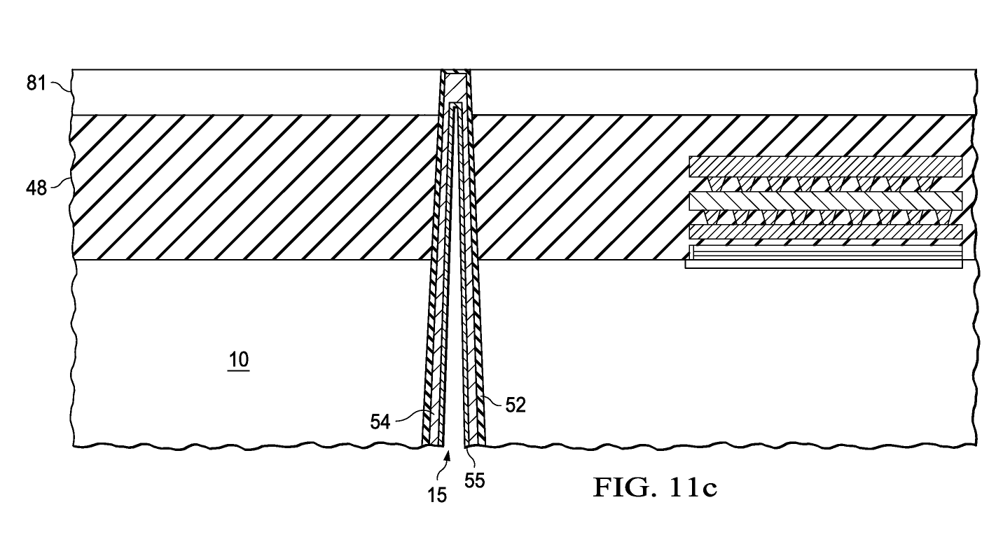

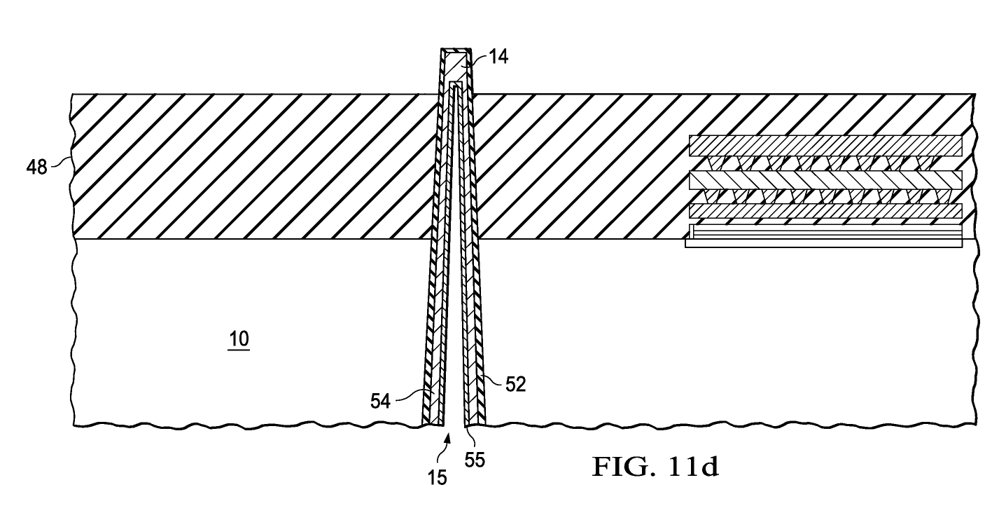

FIG. 11, which includes FIGS. 11a-11d, along with the flow chart of FIG. 12, illustrates an embodiment of the invention describing steps during fabrication of the stacked chips.

Unlike the prior embodiments, in this embodiment, all processes on the front side of a first substrate 10 are completed. This includes forming metallization layers and a passivation layer 48. A sacrificial layer 81 is deposited over the passivation layer 48. The sacrificial layer 81 is selected to comprise a material that etches easily relative to the passivation layer 48. The first substrate 10 is mounted on a carrier 58 and thinned from the back side (FIG. 11a).

Referring to FIG. 11b, a through substrate opening 51 is formed from the back side of the first substrate 10. As illustrated in FIG. 1I c, the through substrate opening 51 is filled with a conductive material as described in FIGS. 5b-5d. In some embodiments, an additional sacrificial layer may be formed between the passivation layer 48 and the carrier 58. The additional sacrificial layer serves as an etch stop layer for the through substrate opening 51. The bottom of the through substrate opening 51 is formed on the additional sacrificial layer.

A sidewall dielectric layer 52 is deposited over the sidewalls and bottom surface of the through substrate opening 51. The sidewall dielectric layer 52 electrically isolates the conductive material in the through substrate via from active devices on the first substrate 10. The sidewall dielectric layer 52 is deposited conformally over the exposed surfaces of the through substrate opening 51. A trench metal liner is deposited over the sidewall dielectric layer 52 prior to filling the through substrate opening 51 with a conductive material. In various embodiments, the trench metal liner comprises a seed layer of copper over a diffusion barrier layer. A conductive fill material 54 is then deposited using, for example, an electroplating process. A conductive outer layer 55 is deposited over the conductive fill material 54 while leaving a first gap 15 within the through substrate opening 51. Unlike the prior embodiments, the first gap 15 opens from the back surface of the first substrate 10 (surface opposite to the active surface).

As illustrated next in FIG. 11d, the sacrificial layer 81 is removed exposing a first protruding tip 14 of a first through substrate via 13. The sacrificial layer 81 is removed based on etch selectivity with respect to the passivation layer 48. However, in some embodiments, a timed etch may be used to remove the sacrificial layer 81 and/or passivation layer 48.

Although described above in various embodiments as stacking chips over each other, the above embodiments also apply to wafer on wafer, die to die, die to wafer stackings as well as chip to circuit board, etc. Embodiments of the invention can be applied to such stackings by minimizing process errors arising, for example, from wafer bending, etc.

Although the present invention and its advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A stacked chip comprising:
a first chip disposed over a substrate, a top surface of the first chip comprising active circuitry;
a first through substrate via disposed within the first chip, the first through substrate via comprising a first protruding tip projecting below a bottom surface of the first chip, the bottom surface being opposite the top surface; and
an opening disposed in the substrate, wherein the first protruding tip of the first chip is disposed within the opening of the substrate.

2. The stacked chip of claim 1, wherein the substrate comprises a second chip, the second chip comprising active circuitry, wherein the opening is disposed in a second through substrate via disposed on the second chip.

3. The stacked chip of claim 2, wherein the second through substrate via comprises a second protruding tip.

4. The stacked chip of claim 3, further comprising a third chip, the third chip comprising active circuitry, wherein the second protruding tip is disposed within a third opening of the third chip.

5. The stacked chip of claim 2, further comprising a layer of adhesive between the first chip and the second chip, the layer of adhesive not disposed in the first opening or the second opening.

6. The stacked chip of claim 1, wherein the first through substrate via comprises a first part with substantially tapered sidewalls and a second part comprising substantially vertical sidewalls.

7. The stacked chip of claim 5, wherein the second part comprises the first protruding tip.

8. The stacked chip of claim 2, wherein the first and the second through substrate vias comprise a conductive fill material.

9. The stacked chip of claim 8, wherein the first and the second through substrate vias further comprise a soldering layer disposed over the conductive fill material.

10. The stacked chip of claim 9, wherein an outer layer of the first protruding tip comprises the soldering layer.

11. The stacked chip of claim 1, wherein sidewalls of the opening comprise a solder layer.

12. The stacked chip of claim 1, wherein the substrate comprises a circuit board.

13. A stacked chip comprising:
a first chip comprising first through substrate vias extending from a top surface to an opposite bottom surface of a first substrate, the top surface comprising active circuitry, the first through substrate vias comprising first features, the first features projecting out of the first substrate; and
a second chip comprising second through substrate vias extending from an upper surface to an opposite lower surface of a second substrate, the upper surface comprising active circuitry, the second through substrate vias comprising second features, wherein inner sidewalls of the second features are disposed on at least a part of outer sidewalls of the first features.

14. The stacked chip of claim 13, wherein the inner sidewalls of the second features comprise a shape and dimension about the same as the outer sidewalls of the first features.

15. The stacked chip of claim 14, wherein the shape of the first and the second through substrate vias, as viewed from a plane view, is designed to promote self-aligning and self-centering.

16. The stacked chip of claim 14, wherein the shape of the first and the second through substrate vias, as viewed from a plane view, is plus shaped, rectangular, or oval.

17. The stacked chip of claim 13, wherein the first and the second through substrate vias are arranged to promote self-aligning and self-centering.

18. The stacked chip of claim 13, wherein the first and the second through substrate vias are arranged radially.

19. A method of forming a stacked chip, the method comprising:
forming a first opening through a first substrate;
partially filling the first opening with a conductive fill material;
forming a protruding tip by recessing the first substrate to expose a portion of the conductive fill material disposed in the first opening;
forming a second opening in a second substrate, the second opening being able to fit the protruding tip; and
stacking the first substrate on the second substrate by fitting the protruding tip into the second opening.

20. The method of claim 19, further comprising depositing a soldering layer over the conductive fill material.

21. The method of claim 20, wherein an outer layer of the protruding tip comprises the soldering layer.

22. The method of claim 19, wherein sidewalls of the second opening comprise a solder layer.

23. The method of claim 19, wherein forming the first opening through the first substrate comprises etching an opening in the first substrate from a top surface, the top surface comprising active devices.

24. The method of claim 19, wherein forming the protruding tip comprises thinning the first substrate from the back surface, the back surface being opposite to a top surface comprising active devices.

25. The method of claim 19, wherein forming the first opening through the first substrate comprises etching an opening in the first substrate from a back surface, the back surface being opposite to a top surface comprising active devices.

26. A method of forming a stacked chip, the method comprising:
forming a first through substrate via through a first substrate, the first through substrate via comprising a protruding tip projecting out of the first substrate;
forming a second through substrate via through a second substrate, the second through substrate via comprising a gap, wherein the gap comprises a dimension such that the protruding tip fits into it; and
stacking the first substrate over the second substrate by fitting the protruding tip into the gap.

27. The method of claim 26, wherein forming the first through substrate via comprises:
forming a first tapered opening through the first substrate;
filling a conductive fill material into the first tapered opening; and
forming the protruding tip by recessing the first substrate to expose a portion of the conductive fill material disposed in the first tapered opening.

28. The method of claim 27, wherein forming the first through substrate via further comprises depositing a solder layer over the conductive fill material.

29. The method of claim 28, wherein the solder layer is deposited within the first through substrate via.

30. The method of claim 28, wherein an outer layer of the protruding tip of the first through substrate via comprises the solder layer.

31. The method of claim 26, wherein forming the second through substrate via comprises:
forming a tapered opening through the second substrate; and
forming the gap by partially filling the conductive fill material into the tapered opening.

32. The method of claim 26, wherein the protruding tip projects out of a top side of the first substrate, the top side comprising active devices.

33. The method of claim 26, wherein the protruding tip projects out of a bottom side of the first substrate, wherein the bottom side is opposite to a top side comprising active devices.
